(19) United States
(12) Patent Application Publication
(10) Pub. No.: US 2024/0389385 A1
(43) Pub. Date: Nov. 21, 2024

(54) DISPLAY PANEL AND MANUFACTURING METHOD THEREOF, DISPLAY DEVICE

(71) Applicants: Chongqing BOE Display Technology Co., Ltd., Chongqing (CN); BOE Technology Group Co., Ltd., Beijing (CN)

(72) Inventor: Lei ZHU, Beijing (CN)

(73) Assignees: Chongqing BOE Display Technology Co., Ltd., Chongqing (CN); BOE Technology Group Co., Ltd., Beijing (CN)

(21) Appl. No.: 18/271,868

(22) PCT Filed: May 27, 2022
(86) PCT No.: PCT/CN2022/095735

§ 371 Date: Jul. 12, 2023

(51) Int. Cl. H10K 59/121; H10K 59/12; H10K 59/122

(52) U.S. Cl. CPC H10K 59/1213; H10K 59/1201; H10K 59/122

(57) ABSTRACT

The present disclosure relates to a display panel and manufacturing method thereof, and a display device. The display panel includes a driving backplane and a pixel definition layer. A partition groove is provided between two adjacent pixel openings of the pixel definition layer and includes a first groove part and a second groove part sequentially provided in a direction away from the driving backplane, and an orthographic projection of the second groove part on the driving backplane is within that of the first groove part on the driving backplane.

### CROSS-REFERENCE TO RELATED APPLICATIONS

The present application is a U.S. National Stage of International Application No. PCT/CN2022/095735 filed on May 27, 2022, the entire contents thereof are incorporated herein by reference.

### TECHNICAL FIELD

The present disclosure relates to the field of display technology, in particular, to a display panel and manufacturing method thereof, and a display device.

### BACKGROUND

Crosstalk is an important indicator for evaluating the quality of a display panel, which mainly refers to that in a display device, an original display state of a pixel is affected by a state change of another pixel or signal electrode.

When an existing organic light-emitting display panel displays a monochrome frame, an adjacent pixel of another color will slightly emit light accordingly, thus causing crosstalk between light-emitting material layers of different colors, and thus affecting the light-emitting quality of the display panel.

It is to be noted that the above information disclosed in the Background section is only for enhancement of understanding of the background of the present disclosure and therefore it may contain information that does not form the prior art that is already known to a person skilled in the art.

### SUMMARY

An object of the present disclosure is to provide a display panel and manufacturing method thereof, and a display device.

An aspect of the present disclosure provides a display panel, including: a driving backplane; a planarization layer group provided on a side of the driving backplane; a plurality of pixel electrodes provided on a side, away from the driving backplane, of the planarization layer group and spaced apart from each other; a pixel definition layer provided on the side, away from the driving backplane, of the planarization layer group, the pixel definition layer being provided with pixel openings exposing the pixel electrodes, a partition groove being provided between two adjacent pixel openings and including a first groove part and a second groove part sequentially provided in a direction away from the driving backplane, and an orthographic projection of the second groove part on the driving backplane being within an orthographic projection of the first groove part on the driving backplane; a light-emitting layer group provided on a side, away from the driving backplane, of the plurality of the pixel electrodes and the pixel definition layer, and including a common layer disconnected in the partition groove; and a common electrode provided on a side, away from the driving backplane, of the light-emitting layer group.

In an embodiment of the present disclosure, the second groove part is a first opening provided between the two adjacent pixel openings, the planarization layer group includes a first planarization layer provided between the driving backplane and the pixel definition layer, and the first groove part is a groove provided in the first planarization layer.

In an embodiment of the present disclosure, the planarization layer group further includes a second planarization layer provided between the first planarization layer and the driving backplane.

In an embodiment of the present disclosure, the second groove part includes a first opening provided between the two adjacent pixel openings, and the planarization layer group includes: a first planarization layer provided between the driving backplane and the pixel definition layer, the second groove part further including a second opening provided in the first planarization layer; and a second planarization layer provided between the first planarization layer and the driving backplane, the first groove part being a groove provided in the second planarization layer.

In an embodiment of the present disclosure, an orthographic projection of the first opening on the driving backplane coincides with an orthographic projection of the second opening on the driving backplane.

In an embodiment of the present disclosure, an orthographic projection of the first opening on the base substrate is within an orthographic projection of the second opening on the base substrate.

In an embodiment of the present disclosure, a first opening is provided between the two adjacent pixel openings, and the planarization layer group includes: a first planarization layer provided between the driving backplane and the pixel definition layer, the first planarization layer being provided with a second opening, and the second opening being connected to the first opening; a second planarization layer provided between the first planarization layer and the driving backplane, the second planarization layer being provided with a groove, and the first groove part being the groove; and a first metal layer provided between the first planarization layer and the second planarization layer and between two adjacent pixel electrodes, and provided with a third opening, the second groove part being the third opening, and the third opening being connected to the second opening.

In an embodiment of the present disclosure, an orthographic projection of the first opening on the driving backplane, an orthographic projection of the second opening on the driving backplane and an orthographic projection of the groove on the driving backplane coincide with each other.

In an embodiment of the present disclosure, an orthographic projection of the first opening on the driving backplane is within an orthographic projection of the second opening on the driving backplane.

In an embodiment of the present disclosure, the orthographic projection of the second opening on the driving backplane is within an orthographic projection of the groove on the driving backplane.

In an embodiment of the present disclosure, a first opening is provided between the two adjacent the pixel openings, the second groove part is the first opening, and the display panel further includes: a blocking layer provided between the driving backplane and the pixel definition layer and between two adjacent pixel electrodes, the blocking layer being provided with a fourth opening, and the first groove part being the fourth opening.

In an embodiment of the present disclosure, a material of the blocking layer is the same as the pixel electrode.

In an embodiment of the present disclosure, a material of the blocking layer is an inorganic material.

In an embodiment of the present disclosure, the driving backplane includes a base substrate and a plurality of thin film transistors provided on a side of the base substrate, and the display panel further includes: a plurality of third electrodes provided between the first planarization layer and the second planarization layer, the pixel electrode being electrically connected with the third electrode through a vial hole in the second planarization layer, and the third electrode being electrically connected with a first electrode or a second electrode of the thin film transistor through a via hole in the first planarization layer.

In an embodiment of the present disclosure, the light-emitting layer group further includes one light-emitting material layer, the common layer includes a first common layer group and a second common layer group, the first common layer group and the second common layer group are respectively provided on two opposite sides of the light-emitting material layer, the first common layer includes at least a hole injection layer and a hole transport layer, and the second common layer includes at least an electron transport layer and an electron injection layer.

In an embodiment of the present disclosure, the light-emitting layer group further includes two light-emitting material layers, the common laver includes a third common layer, a first common layer group and a second common layer group, the third common layer is provided between two adjacent light-emitting material layers, the first common layer group and the second common layer group are respectively provided on sides, away from the third common layer, of the light-emitting material layers, the third common layer is a charge generation layer, the first common layer includes at least a hole injection layer and a hole transport layer, and the second common layer includes at least an electron transport layer and an electron injection layer.

Another aspect of the present disclosure provides a method for manufacturing a display panel, including:
providing a driving backplane;
forming a planarization layer group on a side of the driving backplane:
forming a plurality of pixel electrodes on a side, away from the driving backplane, of the planarization layer group:
forming a pixel definition layer having pixel openings on the planarization layer group, the pixel openings exposing the pixel electrodes;
forming a partition groove between two adjacent pixel openings, the partition groove including a first groove part and a second groove part sequentially provided in a direction away from the driving backplane, and an orthographic projection of the second groove part on the driving backplane being within an orthographic projection of the first groove part on the driving backplane;
forming a light-emitting layer group on a side, away from the driving backplane, of the pixel electrodes, the light-emitting layer group including a common layer, and the common layer being disconnected in the partition groove; and
forming a common electrode on a side, away from the driving backplane, of the light-emitting layer group.

In an embodiment of the present disclosure, the planarization layer group includes a first planarization layer and a second planarization layer sequentially stacked in a direction away from the driving backplane, and forming the partition groove between the two adjacent pixel openings includes:
etching the pixel definition layer to form a first opening, the first opening being a portion of the second groove part;
etching the first planarization layer to form a second opening, the second opening being another portion of the second groove part; and
etching the second planarization layer to form a groove, the recess being the first groove part,
wherein a lateral etching rate of the second planarization layer is greater than a lateral etching rate of the first planarization layer and a lateral etching rate of the pixel definition layer, and the lateral etching rate of the first planarization layer is greater than or equal to the lateral etching rate of the pixel definition layer.

Yet another aspect of the present disclosure provides a display device, including any display panel describe above.

It should be understood that the above general description and the detailed descriptions that follow are only exemplary and explanatory and do not limit the present disclosure.

### BRIEF DESCRIPTION OF THE DRAWINGS

The accompanying drawings herein are incorporated into and form part of the specification, illustrate embodiments consistent with the present disclosure, and are used in conjunction with the specification to explain the principles of the present disclosure. It will be apparent that the accompanying drawings in the following description are only some embodiments of the present disclosure, and that according to these accompanying drawings, a person skilled in the art may obtain other accompanying drawings without creative effort.

FIG. 1 is a schematic structure diagram of a light-emitting layer group of a display panel with a single-layer structure according to an embodiment of the present disclosure.

FIG. 2 is a schematic structure diagram of a light-emitting layer group of a display panel with a stacked structure according to an embodiment of the present disclosure.

FIG. 3 is a schematic structure diagram of a display panel having a first groove part provided in a first planarization layer according to an embodiment of the present disclosure.

FIG. 4 is a schematic structure diagram of another display panel having a first groove part provided in a first planarization layer according to an embodiment of the present disclosure.

FIG. 5 is a schematic structure diagram of a display panel having a second groove part including a first opening and a second opening according to an embodiment of the present disclosure.

FIG. 6 is a schematic structure diagram of another display panel having a second groove part including a first opening and a second opening according to an embodiment of the present disclosure.

FIG. 7 is a schematic structure diagram of a display panel having a second groove part being a third opening according to an embodiment of the present disclosure.

FIG. 8 is a schematic structure diagram of another display panel having a second groove part being a third opening according to an embodiment of the present disclosure.

FIG. 9 is a schematic structure diagram of a further display panel having a second groove part being a third opening according to an embodiment of the present disclosure.

FIG. 10 is a schematic structure diagram of yet further display panel having a second groove part being a third opening according to an embodiment of the present disclosure.

FIG. 11 is a schematic structure diagram of a display panel having a first groove part being a fourth opening according to an embodiment of the present disclosure.

FIG. 12 shows a schematic structure diagram of another display panel having a first groove part being a fourth opening according to an embodiment of the present disclosure.

FIG. 13 is a flowchart of a method for manufacturing a display panel according to an embodiment of the present disclosure.

FIGS. 14-16 are schematic diagrams of a process for making a partition groove of another display panel having a second groove part including a first opening and a second opening according to an embodiment of the present disclosure.

FIGS. 17-19 are schematic diagrams of a process for making a partition groove of a display panel having a first groove part being a fourth opening according to an embodiment of the present disclosure.

FIGS. 20-22 are schematic diagrams of a process for making a partition groove of another display panel having a first groove part being a fourth opening according to an embodiment of the present disclosure.

### DETAILED DESCRIPTION

Example embodiments will now be described more fully with reference to the accompanying drawings. Example embodiments, however, may be embodied in various forms and should not be construed as being limited to the examples set forth herein; rather, these embodiments are provided so that the present disclosure will be thorough and complete, and the concept of example embodiments would be fully conveyed to a person skilled in the art. The same reference numerals in the drawings denote the same or similar structures, and thus their detailed descriptions will be omitted. In addition, the accompanying drawings are only schematic illustrations of the present disclosure and are not necessarily to scale.

Although relative terms such as “up” and “down” are used in this specification to describe the relative relationship of one component with another component shown, these terms are used in this specification only for convenience of the description, for example according to the example orientation described in the accompanying drawings. It is to be understood that if a device shown is turned upside down, the component described as being “up” will become the component described as being “down”. When a structure is “on” another structure, it may mean that the structure is integrally formed on the another structure, or that the structure is disposed “directly” on the another structure, or that the structure is disposed “indirectly” on the another structure via an additional structure.

The terms “a”, “an”, “the”, “said” and “at least one of” are used to indicate the presence of one or more elements/components/etc.; the terms “including” and “having” are used to indicate an open-ended inclusive meaning and that additional elements/components/etc. may be present in addition to the listed elements/components/etc. The terms “first”, “second”, “third” and the like are used only as labels and are not intended to limit the number of the objects thereof.

According to a structure of a light-emitting layer group, a display panel may be divided into an OLED display panel with a single-layer structure and an OLED display panel with a stacked structure. The OLED display panel with the stacked structure has a longer lifetime and lower power consumption than the OLED display panel with the single-layer structure, so the OLED display panel with the stacked structure gradually becomes being widely used.

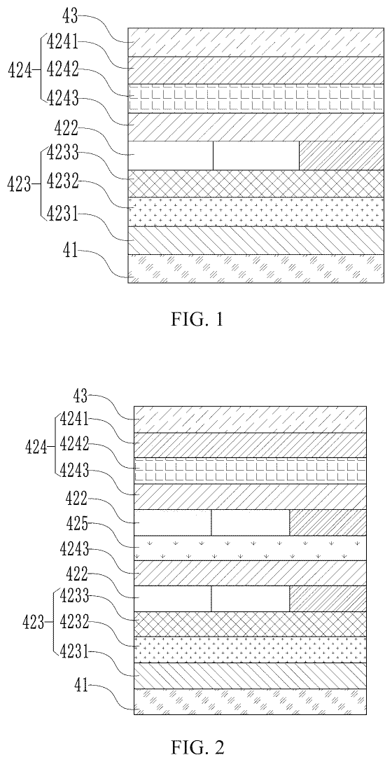

Generally, as shown in FIG. 1, a light-emitting layer group 42 of an OLED display panel with a single-layer structure may include one light-emitting material layer 422 (EML), a first common layer group 423 and a second common layer group. The first common layer group 423 and the second common layer group are respectively provided on opposite sides of the light-emitting material layer. The first common layer includes at least a hole injection layer 4231 (HIL) and a hole transport layer 4232 (HTL), and may further include an electron blocking layer (EBL). The second common layer group includes at least an electron transport layer 4242 (ETL) and an electron injection layer 4241 (EIL), and may further include a hole blocking layer 4243 (HBL). The hole injection layer 4231 is provided on a side of a pixel electrode 41 away from a driving backplane, the hole transport layer 4232 is provided on a side of the hole injection layer 4231 away from the driving backplane, and the electron blocking layer 4233 is provided on a side of the hole transport layer 4232 away from the driving backplane. The light-emitting material layer 422 is provided on a side of the electron blocking layer 4233 away from the driving backplane. The light-emitting material layer 422 may include a red light-emitting material unit, a green light-emitting material unit and a blue light-emitting material unit. The hole blocking layer 4243 is provided on a side of the light-emitting material layer 422 away from the driving backplane, the electron transport layer 4242 is provided on the side of the hole blocking layer 4243 away from the driving backplane, and the electron injection layer 4241 is provided on a side of the electron transport layer 4242 away from the driving backplane.

As shown in FIG. 2, an OLED display panel with a stacked structure includes two sub-light-emitting layer groups. One sub-light-emitting layer group includes one light-emitting material layer 422 and a first common layer group 423. The first common layer group 423 is provided on a side of the light-emitting material layer 422 away from a third common layer 425. The one sub-light-emitting layer group may further include a hole blocking layer (HBL) provided on another side of the light-emitting material layer 422. Another sub-light-emitting layer group includes another light-emitting material layer 422 and a second common layer group 424. The second common layer group 424 is provided on a side of another light-emitting material layer 422 away from the third common layer 425. The third common layer 425 is provided between the two sub-light-emitting layer groups, and the third common layer 425 is a charge generation layer (CGL). The OLED display panel with the stacked structure is provided by connecting the two separate sub-light-emitting layer groups through the third common layer 425. The third common layer 425 has a strong electrical conductivity, which may easily cause lateral leakage and lead to crosstalk between different sub-pixels of different sub-light-emitting layer groups.

The third common layer 425 generates electrons and holes and transfers the electrons and holes efficiently to an adjacent sub-light-emitting layer group. Generally, the third common layer 425 is evaporated on the entire surface by using the same mask plate as that for the hole injection layer 4231 (HTL) and the electron injection layer 4241 (ETL), and the third common layer 425 has a strong conductivity, therefore when a red light-emitting layer in one sub-light-emitting layer group emits light normally, a part of the current thereof flows to a green light-emitting layer, thereby causing the green light-emitting layer to emit light improperly, and thus resulting in visual abnormal display.

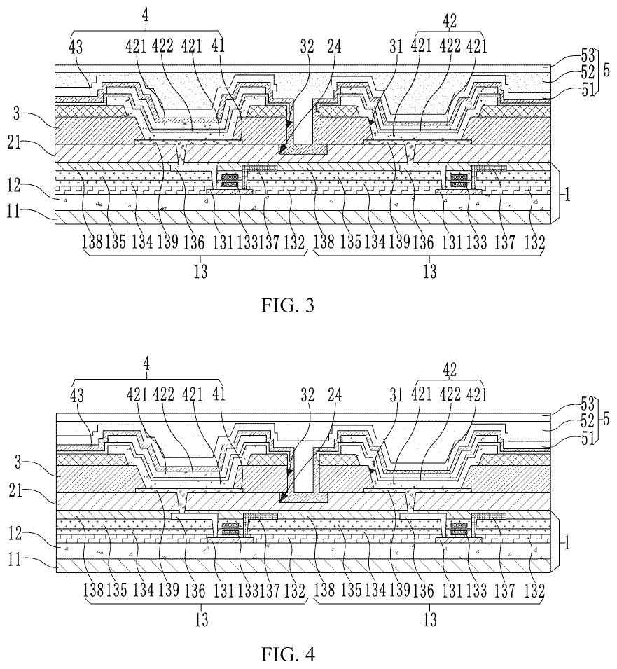

In view of the above, an embodiment of the present disclosure provides a display panel. As shown in FIGS. 3 to 11, the display panel includes a driving backplane 1, a planarization layer group 2, a plurality of pixel electrodes 41, a pixel definition layer 3, a light-emitting layer group 42 and a common electrode 43. The planarization layer group 2 is provided on a side of the driving backplane 1. The plurality of pixel electrodes 41 are provided on a side of the planarization layer group 2 away from the driving backplane 1. The pixel definition layer 3 is provided on the side of the planarization layer group 2 away from the driving backplane 1. The pixel definition layer 3 is provided with pixel openings 31 exposing the pixel electrodes 41. A partition groove is provided between two adjacent pixel openings 31, and the partition groove includes a first groove part and a second groove part provided sequentially in a direction away from the driving backplane 1. An orthographic projection of the second groove part on the driving backplane 1 is within an orthographic projection of the first groove part on the driving backplane 1. The light-emitting layer group 42 is provided on a side of the plurality of pixel electrodes 41 and the pixel definition layer 3 away from the driving backplane 1. The light-emitting layer group 42 includes a common layer, and the common layer is disconnected in a partition groove. The common electrode 43 is provided on a side of the light-emitting layer group 42 away from the driving backplane 1.

The pixel definition layer 3 is provided with the partition groove between two adjacent pixel openings 31, the partition groove includes the first groove part and the second groove part sequentially provided in the direction away from the driving backplane 1, and the orthographic projection of the second groove part on the driving backplane 1 is within the orthographic projection of the first groove part on the driving backplane 1, therefore when forming the common layer, the partition groove disconnects the common layer between different sub-pixels, and a current of a light-emitting material layer of a color will not flow to a light-emitting material layer of another color, thereby reducing crosstalk between light-emitting material layers of different colors due to lateral leakage and avoiding improper light emitting, so that the display of the display panel always remains normal.

It is to be noted that the planarization layer group may include one planarization layer or two or more planarization layers. The orthographic projection of the second groove part on the driving backplane 1 is within the orthographic projection of the first groove part on the driving backplane 1, which means that the area of the orthographic projection of the second groove part on the driving backplane 1 is smaller than the area of the orthographic projection of the first groove part on the driving backplane 1, excluding that the area of the orthographic projection of the second groove part on the driving backplane 1 is equal to the area of the orthographic projection of the first groove part on the driving backplane 1, i.e., that the orthographic projection of the second groove part on the driving backplane 1 coincides with the orthographic projection of the first groove part on the driving backplane 1.

It is to be noted that the common electrode may or may not be broken in the partition groove. Generally, the common electrode breaks in the partition groove, but in an actual formation process, the common electrode may be continuously distributed in the partition groove.

Referring to FIGS. 3 to 11, the driving backplane 1 may include a base substrate 11 and a driving circuit layer, and the driving backplane 1 may further include a buffer layer 12 provided between the base substrate 11 and the driving circuit layer.

The base substrate 11 may be an inorganic material substrate or an organic material substrate. By way of example, in an embodiment of the present disclosure, the material of the base substrate 11 may be a glass material such as soda-lime glass, quartz glass and sapphire glass, or a metal material such as stainless steel, aluminum and nickel. In another embodiment of the present disclosure, the material of the base substrate 11 may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN) naphthalate (PEN), or a combination thereof.

In another embodiment of the present disclosure, the base substrate 11 may also be a flexible base substrate, for example the material of the base substrate 11 may be polyimide (PI). The base substrate 11 may also be a composite of multiple material layers, for example, in an embodiment of the present disclosure, the base substrate 11 may include a bottom film layer, a pressure sensitive adhesive layer, a first polyimide layer and a second polyimide layer sequentially stacked.

In the present disclosure, the driving circuit layer is provided with a driving circuit for driving sub-pixels. In the driving circuit layer, any of the driving circuits may include a transistor and a storage capacitor. Further, the transistor may be a thin film transistor 13, and the thin film transistor 13 may be selected from a top-gate type thin film transistor, a bottom-gate type thin film transistor or a double-gate type thin film transistor. Taking the top-gate type thin film transistor as an example, the thin film transistor 13 may include an active layer 131, a gate insulating layer 132, a gate 133, a first electrode 136 and a second electrode 137.

The active layer 131 is provided on a side of the base substrate 11, and the material of the active layer 131 may be an amorphous silicon semiconductor material, a low temperature polycrystalline silicon semiconductor material, a metal oxide semiconductor material, an organic semiconductor material or other types of semiconductor materials. The thin film transistor may be an N-type thin film transistor or a P-type thin film transistor. The active layer 131 may include a channel region and two doping regions of different doping types located on two sides of the channel region.

The gate insulating layer 132 may cover the active layer 131 and the base substrate 11, and the material of the gate insulating layer 132 is an insulating material such as silicon oxide.

The gate 133 is provided on a side of the gate insulating layer 132 away from the base substrate 11 and faces towards the active layer 131, i.e., the projection of the gate 133 on the base substrate 11 is within the projection of the active layer 131 on the base substrate 11. For example, the projection of the gate 133 on the base substrate 11 coincides with the projection of the channel region of the active layer 131 on the base substrate 11.

The thin film transistor 13 further includes an interlayer insulating layer 134 covering the gate 133 and the gate insulating layer 132, and the thin film transistor 13 further includes an interlayer dielectric layer 135 provided on a side of the interlayer insulating layer 134 away from the base substrate 11. Both the interlayer insulating layer 134 and the interlayer dielectric layer 135 are of insulating materials, but the materials of the interlayer insulating layer 134 and the interlayer dielectric layer 135 may be different.

The first electrode 136 and the second electrode 137 are provided on a surface of the interlayer dielectric layer 135 away from the base substrate 11. The first electrode 136 may be a first source electrode, and the second electrode 137 may be a drain electrode. The first electrode 136 and the second electrode 137 are connected to the active layer 131, for example, the first electrode 136 and the second electrode 137 are respectively connected to two doping regions of a corresponding active layer 131 through via holes.

A protective layer 138 is provided on a side of the first electrode 136 away from the base substrate 11. The protective layer 138 covers the first electrode 136 and the second electrode 137. The planarization layer group 2 is provided on a side of the first electrode 136 and the second electrode 137 away from the base substrate 11. The planarization layer group 2 is provided on a side of the protective layer 138 away from the base substrate 11. The planarization layer group 2 covers the protective layer 138. The surface of the planarization layer group 2 away from the base substrate 11 is flat.

The pixel definition layer 3 and a pixel layer 4 may be provided on a side of the planarization layer group 2 away from the base substrate 11. The pixel definition layer 3 has a plurality of openings, the pixel layer 4 includes a plurality of sub-pixels, and the plurality of sub-pixels are respectively provided in the plurality of openings. The plurality of sub-pixels are distributed on a side of the driving backplane 1 away from the base substrate 11 as an array, and specifically, the sub-pixels may be provided on a side of the planarization layer group 2 away from the base substrate 11. It is to be noted that the sub-pixels may include a red sub-pixel, a green sub-pixel and a blue sub-pixel according to the emitting color.

The pixel layer 4 may include a plurality of pixel electrodes 41, a light-emitting layer group 42 and a common electrode 43. The pixel electrodes 41 are provided on a surface of the driving backplane 1 away from the base substrate 11, the light-emitting layer group 42 is provided on a surface of the pixel electrodes 41 away from the base substrate 11, and the common electrode 43 is provided on a surface of the light-emitting layer group 42 away from the base substrate 11. The common electrode 43 may be or may not be broken in the partition groove.

The pixel electrode 41 is connected to the first electrode 136. When the thin film transistor 13 includes only the first electrode 136, the pixel electrode 41 is connected to the first electrode 136, and the pixel definition layer 3 is provided to cover the pixel electrode 41 and the planarization layer group 2.

The common electrode 43 may be used as a cathode, and the pixel electrode 41 may be used as an anode. The pixel electrode 41 is connected to a positive electrode of a power supply, and the common electrode 43 is connected to a negative electrode of the power supply. A signal may be applied through the pixel electrode 41 and the common electrode 43 to drive the light-emitting layer group 42 to emit light and thus display an image, however the specific light-emitting principle is not described in details here. The light-emitting layer group 42 may include an organic electroluminescent material, for example, the light-emitting layer group 42 may include an auxiliary layer and a light-emitting layer sequentially stacked on the pixel electrode 41. Generally, a patterned region is provided on a mask plate, and the auxiliary layers of sub-pixels of different colors and the light-emitting layers of sub-pixels of different colors are formed by using for example an evaporation process.

In addition, the display panel of the present disclosure may further include an encapsulation layer 5, which is provided on a side of the pixel layer 4 away from the base substrate 11, thereby encapsulating the pixel layer 4 and preventing water and oxygen attack. The encapsulation layer 5 may be a single-layer structure or a multi-layer structure, and the material of the encapsulation layer 5 may include an organic material or an inorganic material, which is not specifically limited herein.

In an embodiment, the encapsulation layer 5 may include a first inorganic encapsulation layer 51, an organic encapsulation layer 52 and a second inorganic encapsulation layer 53. The first inorganic encapsulation layer 51 is provided on a side of the pixel layer 4 away from the base substrate 11, the organic encapsulation layer 52 is provided on a side of the first inorganic encapsulation layer 51 away from the base substrate 11, and the second inorganic encapsulation layer 53 is provided on a side of the organic encapsulation layer 52 away from the base substrate 11.

The first inorganic encapsulation layer 51 and the second inorganic encapsulation layer 53 may be formed of an inorganic material such as silicon nitride (SiN), but is not limited thereto. The first inorganic encapsulation layer 51 and the second inorganic encapsulation layer 53 may be prepared by using Plasma Enhanced Chemical Vapor Deposition (PECVD) or Atomic Layer Deposition (ALD). The organic encapsulation layer 52 may be formed of an organic material that can be cured (which includes light curing or heat curing), specifically, the organic encapsulation layer 52 may be formed of at least one of epoxy resin-based organic material, acrylate-based organic material and silicone-based material. The aforementioned organic encapsulation layer 52 may be prepared by using the Ink Jet Printing (IJP) process or screen printing.

As shown in FIG. 3, the planarization layer group 2 includes a first planarization layer 21. The first planarization layer 21 is provided on a side of the protective layer 138 away from the base substrate 11, and covers the protective layer 138. The surface of the first planarization layer 21 away from the base substrate 11 is flat, and the plurality of pixel electrodes 41 are spaced apart on the side of the planarization layer group 2 away from the driving backplane 1. The portion of the first planarization layer 21 provided between two adjacent pixel electrodes 41 is provided with a groove 24, and the first groove part is the groove 24 provided in the first planarization layer 21. The portion of the pixel definition layer 3 provided between two adjacent pixel openings 31 is provided with a first opening 32, and the second groove part is the first opening 32.

The display panel shown in FIG. 4 differs from the display panel of FIG. 3 in that the planarization layer group 2 includes a second planarization layer 22, which is provided between the first planarization layer 21 and the driving backplane 1. The display panel may further include a third electrode 139, which is provided between the first planarization layer 21 and the second planarization layer 22, and the third electrode 139 may be a second source electrode. Both the first planarization layer 21 and the second planarization layer 22 are provided with via holes, the pixel electrode 41 is electrically connected to the third electrode 139 through the via hole in the first planarization layer 21, and the third electrode 139 is electrically connected to the first electrode 136 through the via hole in the second planarization layer 22.

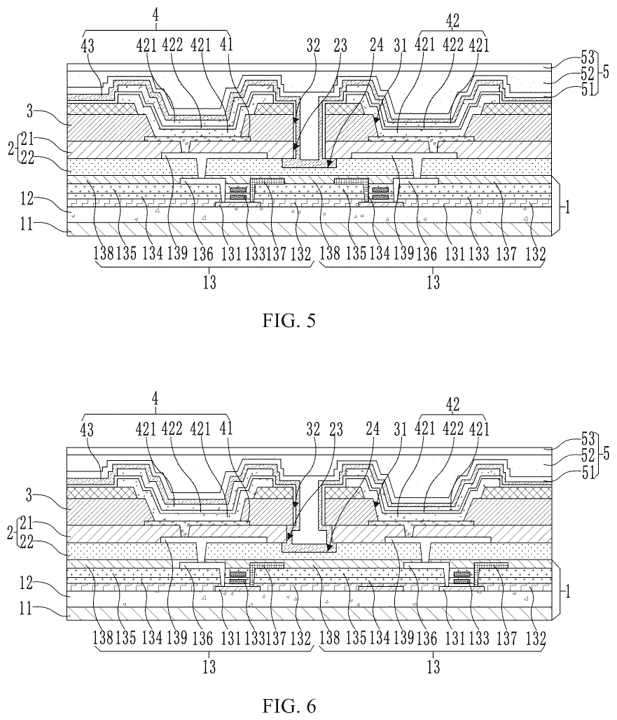

The display panel shown in FIG. 5 differs from the display panel shown in FIG. 4 in that the second groove part includes a second opening 23 in the first planarization layer 21 in addition to the first opening 32 provided between two adjacent pixel openings 31. The second planarization layer 22 is provided between the first planarization layer 21 and the driving backplane 1. The second planarization layer 22 is provided with a groove 24, and the first groove part is the groove 24. It is to be noted that the orthographic projection of the first opening 32 on the driving backplane 1 coincides with the orthographic projection of the second opening 23 on the driving backplane 1.

The display panel shown in FIG. 6 differs from the display panel shown in FIG. 5 in that the orthographic projection of the first opening 32 on the base substrate 11 is within the orthographic projection of the second opening 23 on the base substrate 11, specifically in that the area of the orthographic projection of the second groove part on the driving backplane 1 is less than the area of the orthographic projection of the first groove part on the driving backplane 1, excluding that the area of the orthographic projection of the second groove part on the driving backplane 1 is equal to the area of the orthographic projection of the first groove part on the driving backplane 1, i.e., that the orthographic projection of the second groove part on the driving backplane 1 coincides with the orthographic projection of the first groove part on the driving backplane 1.

It is to be understood that the orthographic projection of the first opening 32 on the driving backplane 1 is smaller than the orthographic projection of the second opening 23 on the driving backplane 1 and that the orthographic projection of the second opening 23 on the driving backplane 1 is smaller than the orthographic projection of the groove 24 on the driving backplane 1, so that the partition groove includes two stepped parts. When forming the third common layer, the third common layer may be disconnected in a first stepped part, and even if the third common layer is not disconnected in the first stepped part, it may be disconnected in the second stepped part, which effectively prevents the current from a light-emitting material layer of one color in one sub-light-emitting layer group 421 from flowing to a light-emitting material layer of another color in another sub-light-emitting layer group 421.

The display panel shown in FIGS. 7 to 9 differs from the display panel of FIG. 5 in that the display panel further includes a first metal layer 6, which is provided between the first planarization layer 21 and the second planarization layer 22 and is located between two adjacent pixel electrodes 41. The first metal layer 6 is provided with a third opening 61, the second groove part is the third opening 61, and the first groove part is the groove 24 provided in the second planarization layer 22. The first opening 32 in the pixel definition layer 3 and the second opening 23 in the first planarization layer 21 are connected to the third opening 61, therefore when forming the third common layer, the third common layer may enter into the partition groove and be disconnected in the partition groove. It is to be noted that the first metal layer 6 may be formed in the same layer and of the same material as that of the third electrode 139.

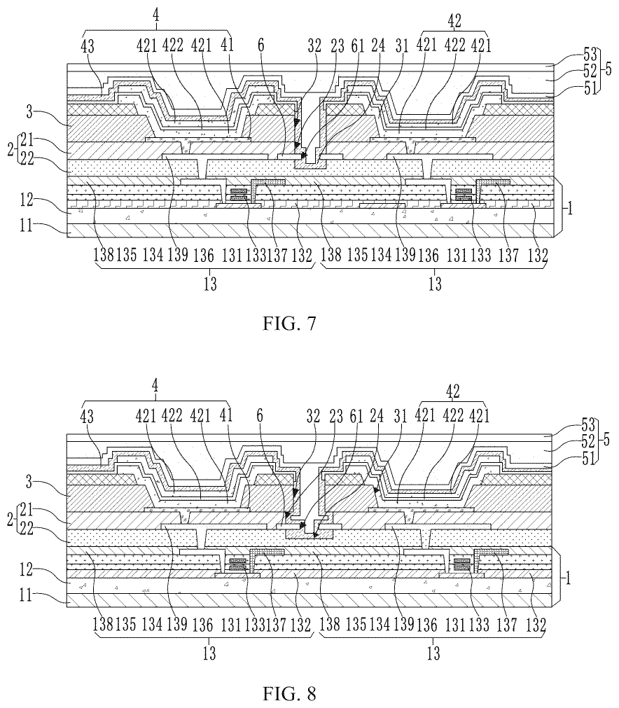

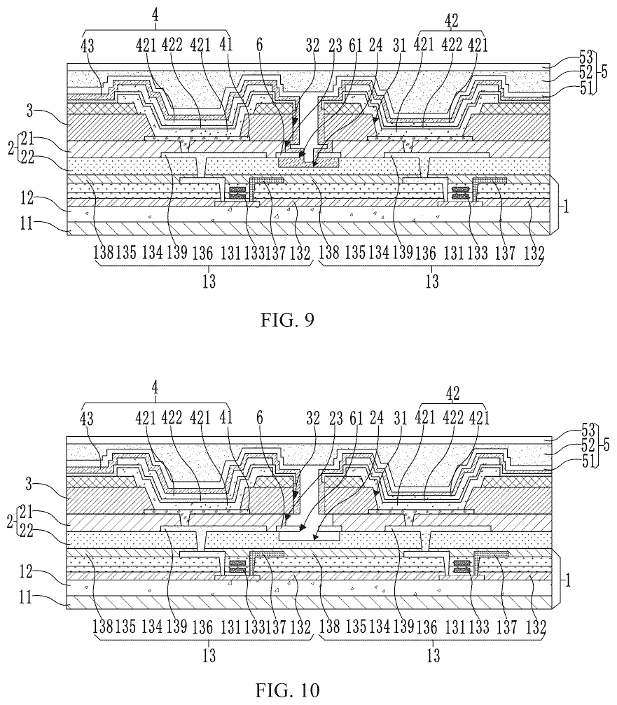

As shown in FIG. 7, the orthographic projection of the first opening 32 on the driving backplane 1, the orthographic projection of the second opening 23 on the driving backplane 1 and the orthographic projection of the groove 24 on the driving backplane 1 coincide with each other. It may also be as shown in FIG. 8 that, the orthographic projection of the first opening 32 on the driving backplane 1 is within the orthographic projection of the second opening 23 on the driving backplane 1, and the orthographic projection of the second opening 23 on the driving backplane 1 coincides with the orthographic projection of the groove 24 on the driving backplane 1. It may also be as shown in FIG. 9 that, the orthographic projection of the first opening 32 on the driving backplane 1 is within the orthographic projection of the second opening 23 on the driving backplane 1, and the orthographic projection of the second opening 23 on the driving backplane 1 is within the orthographic projection of the groove 24 on the driving backplane 1.

In the display panel shown in FIGS. 8 to 10, the first opening 32 and the second opening 23 may form a stepped hole. When forming the third common layer, the third common layer may be disconnected in the stepped hole formed by the first opening 32 and the second opening 23, and even if the third common layer is not disconnected in the stepped hole, it may be disconnected in the partition groove formed by the third opening 61 and the groove 24, which may further reduce or eliminate the flow of the current from a light-emitting material layer of one color in one sub-light-emitting layer group 421 to a light-emitting material layer of another color in another sub-light-emitting layer group 421. FIG. 10 differs from FIG. 9 in that the common electrode in FIG. 9 is continuously distributed in the partition groove and the common electrode in FIG. 10 is broken/disconnected in the partition groove.

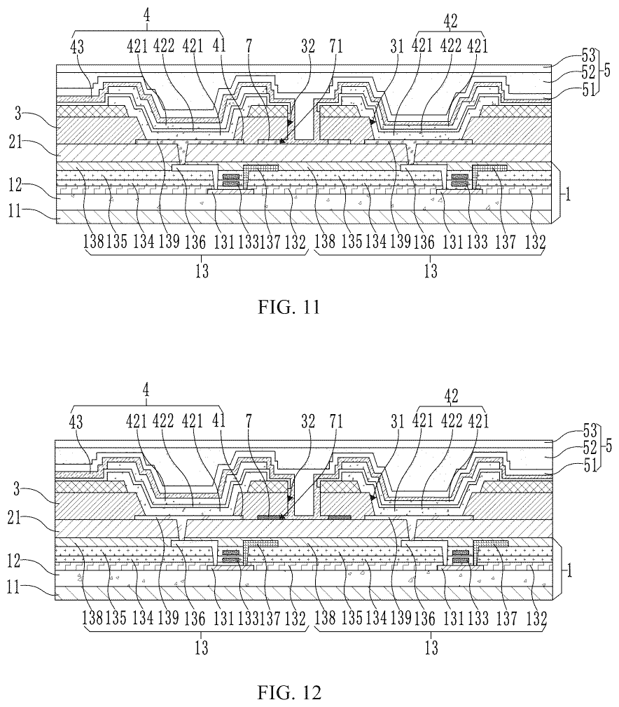

As shown in FIGS. 11 and 12, the display panel may further include a blocking layer 7, and the blocking layers 7 are spaced apart between two adjacent pixel electrodes 41. The blocking layer 7 and the pixel electrodes 41 are on a same side of the planarization layer group 2. The blocking layer 7 is provided with a fourth opening 71, and the first groove part is the fourth opening 71. The pixel definition layer 3 is provided on a side of the planarization layer group 2 away from the driving backplane 1, and the pixel definition layer 3 is provided with pixel openings 31 that expose the pixel electrodes 41. The first opening 32 is provided between two adjacent pixel openings 31, and the second groove part is the first opening 32.

It is to be noted that the material of the blocking layer 7 may be the same as the material of the pixel electrodes 41, and the specific material of the blocking layer 7 may mainly be ITO and Ag. The material of the blocking layer 7 may also be the same as the material of the protective layer 138, and the specific material of the blocking layer 7 may be an inorganic material.

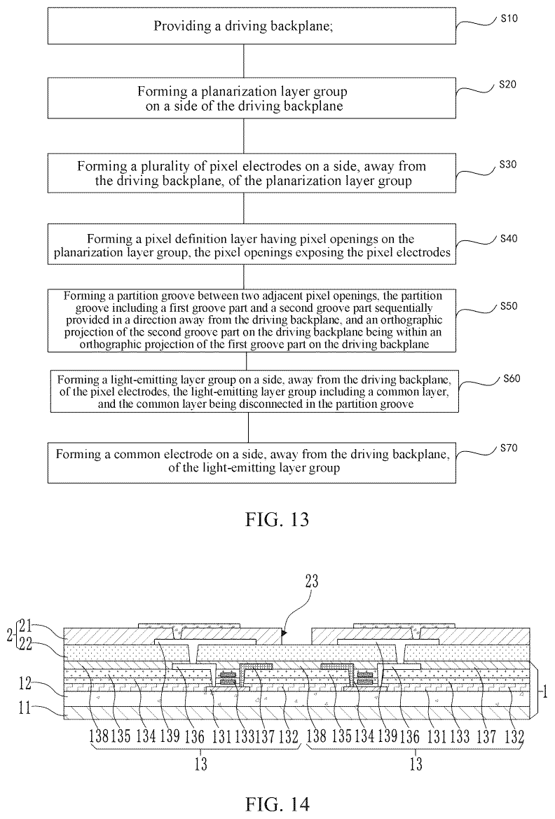

An embodiment of the present disclosure provides a method for manufacturing a display panel. As shown in FIG. 13, the method may include:
step S10, providing a driving backplane;
step S20, forming a planarization layer group on a side of the driving backplane;
step S30, forming a plurality of pixel electrodes on a side, away from the driving backplane, of the planarization layer group;
step S40, forming a pixel definition layer having pixel openings on the planarization layer group, the pixel openings exposing the pixel electrodes;
step S50, forming a partition groove between two adjacent pixel openings, the partition groove including a first groove part and a second groove part sequentially provided in a direction away from the driving backplane, and an orthographic projection of the second groove part on the driving backplane being within an orthographic projection of the first groove part on the driving backplane;
step S60, forming a light-emitting layer group on a side, away from the driving backplane, of the pixel electrodes, the light-emitting layer group including a common layer, and the common layer being disconnected in the partition groove; and
step S70, forming a common electrode on a side, away from the driving backplane, of the light-emitting layer group.

The method may further include: forming an encapsulation layer on a side of the common electrode away from the driving backplane.

Step S50 is described in detail below.

It is described in detail with respect to the display panel shown in FIG. 3.

Step S10 may specifically include: preparing a pixel driving circuit and a corresponding film layer on the base substrate 11. This process is the process for the existing driving backplane 1 and will not be described in detail here.

Step S20 may specifically include: forming the first planarization layer 21 on the side of the driving backplane 1, the planarization layer group 2 including only the first planarization layer 21.

Step S30 may specifically include: coating a metal layer for the pixel electrodes 41 on the planarization layer group 2 and forming the pixel electrodes 41 by exposure development etching.

Step S40 may specifically include: coating the pixel definition layer 3 and forming the pixel openings 31 by exposure development.

Step S50 may specifically include: completely etching away, in the thickness direction, the portion of the pixel definition layer 3 between two adjacent pixel openings 31 to form the first opening 32, the first opening 32 being the second groove part; and by using the pixel definition layer 3 with the formed pixel openings 31 as a mask layer, partially etching, in the thickness direction, the portion of the first planarization layer 21 between the two adjacent pixel electrodes 41 to form the groove 24, the groove 24 being the first groove part.

It is described in detail with respect to the display panel shown in FIG. 4.

Step S20 may specifically include: forming the second planarization layer 22 on a side of the driving backplane 1, forming the third electrode 139 on the side of the second planarization laver 22 away from the driving backplane 1, connecting the third electrode 139 to the first electrode 136 or the second electrode 137 of the thin film transistor 13 through a via hole in the second planarization layer 22, and forming the first planarization layer 21 on the side of the second planarization layer 22 and the third electrode 139 away from the driving backplane 1.

The specific process of step S50 is the same as the specific process of step S50 in FIG. 3 and therefore will not be repeated herein.

It is described in detail with respect to the display panel shown in FIG. 5.

The specific process of step S20 is the same as the specific process of step S20 in FIG. 4 and is therefore not repeated herein.

Step S50 may specifically include:

completely etching away, in the thickness direction, the portion of the pixel definition layer 3 between two adjacent pixel openings 31 to form the first opening 32, the first opening 32 being the second groove part; completely etching away, in the thickness direction, the portion of the first planarization layer 21 between the two adjacent pixel electrodes 41 to form the second opening 23, the second opening 23 being part of the second groove part; partially etching, in the thickness direction, the portion of the second planarization layer 22 between the two adjacent pixel electrodes 41 to form the groove 24, the groove 24 being the first groove part.

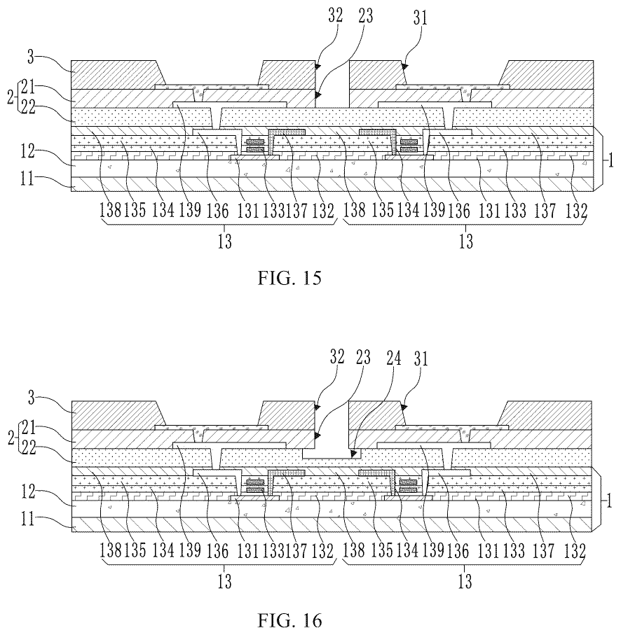

As shown in FIG. 14, the second opening 23 may be provided after the coating of the first planarization layer 21 is completed so as to achieve the patterning of the first planarization layer 21. As shown in FIG. 15, the first opening 32 may be formed at the same time as providing the pixel opening 31 so as to achieve the patterning of the pixel definition layer 3. As shown in FIG. 16, the patterned second planarization layer 22 and the patterned pixel definition layer 3 may be used as a mask layer to etch the second planarization layer 22 to form the groove 24.

A lateral etching rate of the pixel definition layer 3 is equal to a lateral etching rate of the first planarization layer 21, and a lateral etching rate of the second planarization layer 22 is greater than the lateral etching rate of the first planarization layer 21 and the lateral etching rate of the pixel definition layer 3.

It is described in detail with respect to the display panel shown in FIG. 6.

The specific process of step S20 is the same as the specific process of step S20 in FIG. 5, and the specific process of step S50 is the same as the specific process of step S50 in FIG. 5, and therefore these steps will not be repeated.

The difference is that the lateral etching rate of the pixel definition layer 3 is less than the lateral etching rate of the first planarization layer 21.

It is described in detail with respect to the display panel shown in FIG. 7.

Step S20 may specifically include: forming the second planarization layer 22 on a side of the driving backplane 1, forming the third electrode 139 on the side of the second planarization layer 22 away from the driving backplane 1, and at the same time forming the first metal layer 6 between two adjacent pixel electrodes 41, and forming the first planarization layer 21 on the side of the second planarization layer 22 and the third electrode 139 away from the driving backplane 1.

Step S50 may specifically include:

completely etching away, in the thickness direction, the portion of the pixel definition layer 3 between two adjacent pixel openings 31 to form the first opening 32; completely etching away, in the thickness direction, the portion of the first planarization layer 21 between the two adjacent pixel electrodes 41 to form the second opening 23; completely etching away, in the thickness direction, the portion of the first metal layer 6 between the two adjacent pixel electrodes 41 to form the third opening 61, the third opening 61 being the second groove part; and partially etching, in the thickness direction, the portion of the second planarization layer 22 between the two adjacent pixel electrodes 41 to form the groove 24, the groove 24 being the first groove part.

The lateral etching rate of the pixel definition layer 3, the lateral etching rate of the first planarization layer 21, and the lateral etching rate of the second planarization layer 22 are the same.

It is described in detail with respect to the display panel shown in FIG. 8.

The specific process of step S20 is the same as the specific process of step S20 in FIG. 7, and the specific process of step S50 is the same as the specific process of step 550 in FIG. 7, therefore these steps are not repeated herein.

The difference is that the lateral etching rate of the pixel definition layer 3 is less than the lateral etching rate of the first planarization layer 21, and the lateral etching rate of the first planarization layer 21 is the same as the lateral etching rate of the second planarization layer 22.

It is described in detail with respect to the display panel shown in FIGS. 8 and 9.

The specific process of step S20 is the same as the specific process of step S20 in FIG. 8, and the specific process of step S50 is the same as the specific process of step S50 in FIG. 8, therefore these steps are not repeated herein.

The difference is that the lateral etching rate of the first planarization layer 21 is less than the lateral etching rate of the second planarization layer 22.

It is described in detail with respect to the display panel shown in FIG. 11.

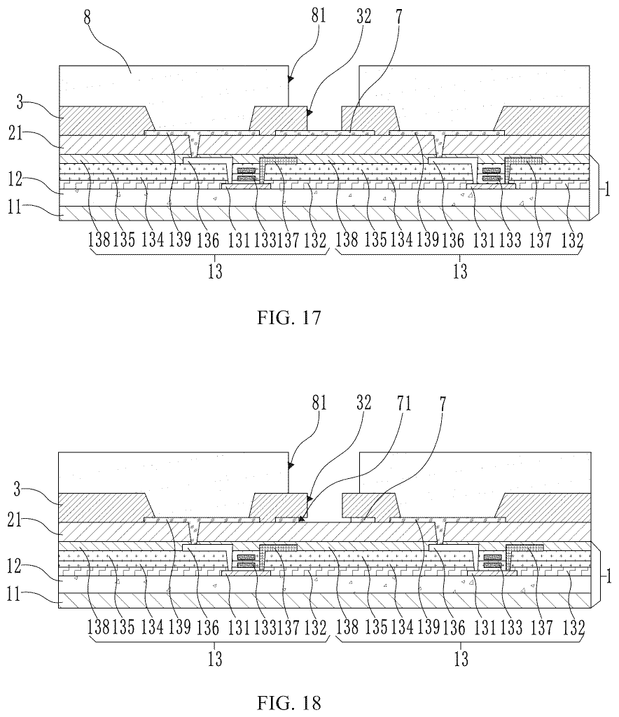

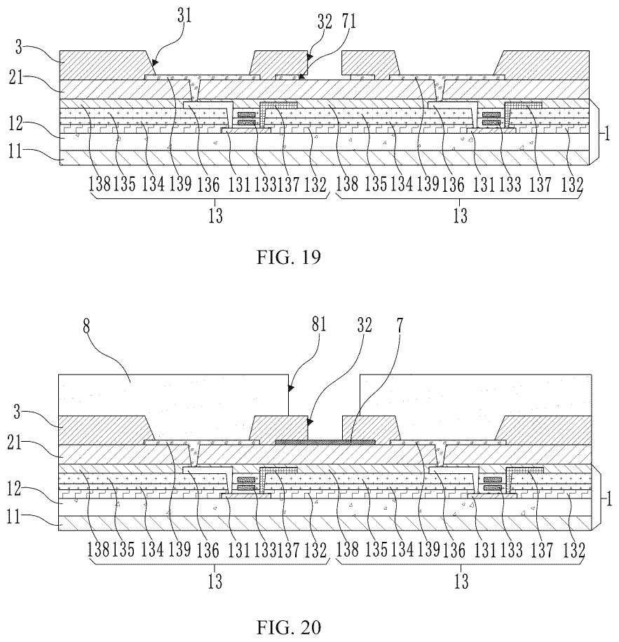

Step S50 may specifically include: as shown in FIG. 17, performing photolithography on the pixel definition layer 3 to form the first opening 32 between two adjacent pixel openings 31, then coating a photoresist layer 8 to cover the pixel definition layer 3, the plurality of pixel electrodes 41 and the plurality of blocking layers 7, forming a to-be-etched area 81 in the photoresist layer 8 by a photolithography process; as shown in FIG. 18, forming a fourth opening 71 in the blocking layer 7 by etching the blocking layer 7; and as shown in FIG. 19, removing the remaining part of the photoresist layer 8 by the photolithography process, the first opening 32 being the second groove part and the fourth opening 71 being the first groove part.

It is to be noted that in the method for manufacturing the display panel of FIG. 11, the patterning of the photoresist layer 8 is achieved by a corresponding mask plate, and the patterning of the blocking layer 7 is achieved in the process of forming the pixel electrodes 41.

It is described in detail with respect to the display panel shown in FIG. 12.

The method may also include: forming the blocking layer 7 of inorganic material on the side of the planarization layer group 2 away from the driving backplane 1 before forming the pixel electrodes 41; and retaining the blocking layer 7 of inorganic material between two sub-pixels by a photolithography process and an etching process.

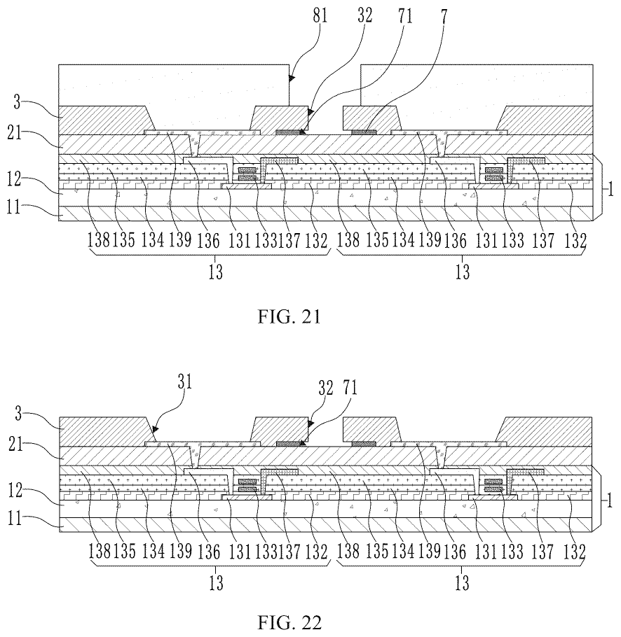

As shown in FIGS. 20 to 22, step S50 is substantially the same as the specific process of step 50 in FIG. 11 and therefore will not be repeated here.

In the method for manufacturing the display panel of FIG. 12, the patterning of the photoresist layer 8 is achieved by a corresponding mask plate, and the patterning of the blocking layer 7 of inorganic material is achieved by a corresponding mask plate.

It is to be noted that although the individual steps of the method for manufacturing the display panel in the present disclosure are described in the accompanying drawings in a particular order, it is not required or implied that the steps must be performed in that particular order or that all of the steps shown must be performed to achieve the desired result. Additional or alternatively, some steps may be omitted, a plurality of steps may be combined into one step for execution, and/or one step may be divided into a plurality of steps for execution, and so on.

A person skilled in the art may easily conceive other embodiments of the present disclosure upon consideration of the specification and practice of the invention disclosed herein. The present application is intended to cover any variation, use or adaptation of the present disclosure that follows the general principle of the present disclosure and includes a common knowledge or conventional technical means in the art that is not disclosed herein. The specification and embodiments are to be considered exemplary only and the true scope and spirit of the present disclosure is indicated by the appended claims.

1. A display panel, comprising:
a driving backplane;
a planarization layer group provided on a side of the driving backplane;
a plurality of pixel electrodes provided on a side, away from the driving backplane, of the planarization layer group and spaced apart from each other;
a pixel definition layer provided on the side, away from the driving backplane, of the planarization layer group, the pixel definition layer being provided with pixel openings exposing the pixel electrodes, a partition groove being provided between two adjacent pixel openings and comprising a first groove part and a second groove part sequentially provided in a direction away from the driving backplane, and an orthographic projection of the second groove part on the driving backplane being within an orthographic projection of the first groove part on the driving backplane;
a light-emitting layer group provided on a side, away from the driving backplane, of the plurality of the pixel electrodes and the pixel definition layer, and comprising a common layer disconnected in the partition groove; and
a common electrode provided on a side, away from the driving backplane, of the light-emitting layer group.

2. The display panel according to claim 1, wherein the second groove part is a first opening provided between the two adjacent pixel openings, the planarization layer group comprises a first planarization layer provided between the driving backplane and the pixel definition layer, and the first groove part is a groove provided in the first planarization layer.

3. The display panel according to claim 2, wherein the planarization layer group further comprises a second planarization layer provided between the first planarization layer and the driving backplane.

4. The display panel according to claim 1, wherein the second groove part comprises a first opening provided between the two adjacent pixel openings, and the planarization layer group comprises:
a first planarization layer provided between the driving backplane and the pixel definition layer, the second groove part further comprising a second opening provided in the first planarization layer; and
a second planarization layer provided between the first planarization layer and the driving backplane, the first groove part being a groove provided in the second planarization layer.

5. The display panel according to claim 4, wherein an orthographic projection of the first opening on the driving backplane coincides with an orthographic projection of the second opening on the driving backplane.

6. The display panel according to claim 4, wherein an orthographic projection of the first opening on the driving backplane is within an orthographic projection of the second opening on the driving backplane.

7. The display panel according to claim 1, wherein a first opening is provided between the two adjacent pixel openings, and the planarization layer group comprises:
a first planarization layer provided between the driving backplane and the pixel definition layer, the first planarization layer being provided with a second opening, and the second opening being connected to the first opening;
a second planarization layer provided between the first planarization layer and the driving backplane, the second planarization layer being provided with a groove, and the first groove part being the groove; and
a first metal layer provided between the first planarization layer and the second planarization layer and between two adjacent pixel electrodes, and provided with a third opening, the second groove part being the third opening, and the third opening being connected to the second opening.

8. The display panel according to claim 7, wherein an orthographic projection of the first opening on the driving backplane, an orthographic projection of the second opening on the driving backplane and an orthographic projection of the groove on the driving backplane coincide with each other.

9. The display panel according to claim 7, wherein an orthographic projection of the first opening on the driving backplane is within an orthographic projection of the second opening on the driving backplane.

10. The display panel according to claim 9, wherein the orthographic projection of the second opening on the driving backplane is within an orthographic projection of the groove on the driving backplane.

11. The display panel according to claim 4, wherein a first opening is provided between the two adjacent the pixel openings, the second groove part is the first opening, and the display panel further comprises:
a blocking layer provided between the driving backplane and the pixel definition layer and between two adjacent pixel electrodes, the blocking layer being provided with a fourth opening, and the first groove part being the fourth opening.

12. The display panel according to claim 11, wherein a material of the blocking layer is the same as the pixel electrode.

13. The display panel according to claim 11, wherein a material of the blocking layer is an inorganic material.

14. The display panel according to claim 3, wherein the driving backplane comprises a base substrate and a plurality of thin film transistors provided on a side of the base substrate, and the display panel further comprises:
a plurality of third electrodes provided between the first planarization layer and the second planarization layer, the pixel electrode being electrically connected with the third electrode through a vial hole in the second planarization layer, and the third electrode being electrically connected with a first electrode or a second electrode of the thin film transistor through a via hole in the first planarization layer.

15. The display panel according to claim 1, wherein the light-emitting layer group further comprises one light-emitting material layer, the common layer comprises a first common layer group and a second common layer group, the first common layer group and the second common layer group are respectively provided on two opposite sides of the light-emitting material layer, the first common layer comprises at least a hole injection layer and a hole transport layer, and the second common layer comprises at least an electron transport layer and an electron injection layer.

16. The display panel according to claim 1, wherein the light-emitting layer group further comprises two light-emitting material layers, the common layer comprises a third common layer, a first common layer group and a second common layer group, the third common layer is provided between the two light-emitting material layers, the first common layer group and the second common layer group are respectively provided on sides, away from the third common layer, of the two light-emitting material layers, the third common layer is a charge generation layer, the first common layer comprises at least a hole injection layer and a hole transport layer, and the second common layer comprises at least an electron transport layer and an electron injection layer.

17. A method for manufacturing a display panel, comprising:
providing a driving backplane;
forming a planarization layer group on a side of the driving backplane;
forming a plurality of pixel electrodes on a side, away from the driving backplane, of the planarization layer group;
forming a pixel definition layer having pixel openings on the planarization layer group, the pixel openings exposing the pixel electrodes;
forming a partition groove between two adjacent pixel openings, the partition groove comprising a first groove part and a second groove part sequentially provided in a direction away from the driving backplane, and an orthographic projection of the second groove part on the driving backplane being within an orthographic projection of the first groove part on the driving backplane;
forming a light-emitting layer group on a side, away from the driving backplane, of the pixel electrodes, the light-emitting layer group comprising a common layer, and the common layer being disconnected in the partition groove; and
forming a common electrode on a side, away from the driving backplane, of the light-emitting layer group.

18. The method for manufacturing the display panel according to claim 17, wherein the planarization laver group comprises a first planarization laver and a second planarization layer sequentially stacked in a direction away from the driving backplane, and forming the partition groove between the two adjacent pixel openings comprises:
etching the pixel definition layer to form a first opening, the first opening being a portion of the second groove part;
etching the first planarization layer to form a second opening, the second opening being another portion of the second groove part; and
etching the second planarization layer to form a groove, the recess being the first groove part,
wherein a lateral etching rate of the second planarization layer is greater than a lateral etching rate of the first planarization layer and a lateral etching rate of the pixel definition layer, and the lateral etching rate of the first planarization layer is greater than or equal to the lateral etching rate of the pixel definition layer.

19. A display device, comprising a display panel comprising:
a driving backplane;
a planarization laver group provided on a side of the driving backplane;
a plurality of pixel electrodes provided on a side, away from the driving backplane, of the planarization layer group and spaced apart from each other;
a pixel definition layer provided on the side, away from the driving backplane, of the planarization laver group, the pixel definition laver being provided with pixel openings exposing the pixel electrodes, a partition groove being provided between two adjacent pixel openings and comprising a first groove part and a second groove part sequentially provided in a direction away from the driving backplane, and an orthographic projection of the second groove part on the driving backplane being within an orthographic projection of the first groove part on the driving backplane;
a light-emitting layer group provided on a side, away from the driving backplane, of the plurality of the pixel electrodes and the pixel definition layer, and comprising a common laver disconnected in the partition groove; and
a common electrode provided on a side, away from the driving backplane, of the light-emitting layer group.

20. The display device according to claim 19, wherein the second groove part is a first opening provided between the two adjacent pixel openings, the planarization layer group comprises a first planarization layer provided between the driving backplane and the pixel definition layer, and the first groove part is a groove provided in the first planarization layer.
